(19) United States
(12) Patent Application Publication
(10) Pub. No.: US 2010/0328985 A1
(43) Pub. Date: Dec. 30, 2010

(54) SEMICONDUCTOR DEVICE HAVING PLURAL CIRCUIT BLOCKS LAID OUT IN A MATRIX FORM

(75) Inventors: Yuki MIURA, Tokyo (JP); Hisayuki NAGAMINE, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/824,762

(22) Filed: Jun. 28, 2010

(30) Foreign Application Priority Data
Jun. 29, 2009 (JP) 2009-154066

(51) Int. Cl. G11C 5/06; G11C 29/00; G11C 8/00; G11C 17/16

(52) U.S. Cl. 365/72; 365/200; 365/230.03; 365/225.7

(57) ABSTRACT

To include an input circuit block to which a plurality of bits are input and a processing circuit block that processes an internal signal output from the input circuit block. The input circuit block includes a plurality of unit input circuits arranged in an X direction to which the bits are input, respectively. Each of the unit input circuits includes an input wiring pattern that extends in a Y direction and a transistor of which a control electrode is connected to a corresponding one of the input wiring pattern. Coordinates of the input wiring pattern and the transistor corresponding to the input wiring pattern in the X direction do not overlap with each other. With this arrangement, by sharing the input wiring pattern between circuit blocks adjacent to each other in the Y direction, it is possible to reduce the number of pre-decode wirings.

### BACKGROUND OF THE INVENTION

1. Field of the Invention

The present invention relates to a semiconductor device, and more particularly relates to a semiconductor device in which a plurality of circuit blocks to which a pre-decoded signal is supplied are laid out in a matrix form.

2. Description of Related Art

A semiconductor memory device such as DRAM (Dynamic Random Access Memory) often includes a redundant circuit for saving defective addresses in the device. The redundant circuit includes a plurality of fuse elements for storing an address of a defective word line or a defective bit line. When the address stored in the fuse elements matches an address for which an access is requested, an alternative access is performed to a redundant word line or a redundant bit line instead of the defective word line or the defective bit line. With this operation, an address assigned to the defective word line or the defective bit line is saved, so that the device is handled as a good chip.

The alternative access to the redundant word line or the redundant bit line is performed by switching an operation of a row decoder or a column decoder. However, because the fuse elements described above are generally arranged together in a fuse area away from the row decoder or the column decoder, a relatively long signal line is required to connect the fuse area and the row decoder or the column decoder.

Beside, because the number of bits of a redundant signal output from the fuse area is considerably large, when the redundant signal is supplied to the row decoder or the column decoder without any modification, a large number of long signal lines are required to transmit the redundant signal, a considerably large wiring area has to be occupied.

Japanese Patent Application Laid-open Nos. 2005-229061, 2007-206887, and H11-3983 discloses examples of a semiconductor device having a plurality of circuit blocks.

### SUMMARY

The inventors of the present invention has devised a method of encoding the redundant signal on the fuse area side and supplying an encoded redundant signal to the row decoder or the column decoder instead of supplying the redundant signal as it is to the row decoder or the column decoder.

However, because the amount of information in the redundant signal is considerably large, when the encoded redundant signal is supplied as it is to the row decoder or the column decoder, a circuit size of the row decoder or the column decoder is inevitably increased, and accordingly its operation becomes complicated. By pre-decoding the encoded redundant signal near the row decoder or the column decoder and performing a latch operation using a pre-decoded redundant signal, the circuit size can be reduced, and accordingly the operation can be simplified. In this case, the pre-decoded redundant signal is supplied to a latch circuit block that is laid out in a matrix form, in which a predetermined latch operation is performed.

However, when the pre-decoded redundant signal is supplied to a plurality of latch circuit blocks, unlike the case that a redundant signal that is not decoded or a redundant signal that is completely decoded is supplied to the latch circuit block, an additional problem occurs as follows. When the redundant signal that is completely decoded is supplied to the latch circuit block, because it is only necessary to input, for example, a 1-bit signal to one latch circuit block, the layout of signal lines does not become so complicated. On the contrary, when the redundant signal that is not decoded is supplied to the latch circuit block, because it is only necessary to input the same signal to a plurality of latch circuit blocks, the layout of signal lines does not also become so complicated.

On the other hand, when the pre-decoded redundant signal is supplied to a plurality of latch circuit blocks, among a plurality of bits included in the pre-decoded redundant signal, a part of the bits needs to be supplied to a corresponding latch circuit block. Furthermore, each of the bits is shared by some latch circuit blocks. For this reason, the layout of signal lines becomes relatively complicated, resulting in occupation of a large wiring area.

The above problems are not ones occurring only in redundant circuits, but are problems commonly occur in semiconductor devices in which a plurality of circuit blocks to which a pre-decoded signal is supplied are laid out in a matrix form.

In one embodiment, there is provided a semiconductor device comprising a plurality of circuit blocks arranged in a matrix form in a first direction and a second direction that intersects with the first direction, wherein each of the circuit blocks includes an input circuit block to which a plurality of bits included in a pre-decoded signal are supplied, and a processing circuit block that processes an internal signal output from the input circuit block, the input circuit block and the processing circuit block are arranged side by side in the first direction, the input circuit block includes a plurality of unit input circuits that is arranged in the first direction and to which corresponding bits of the pre-decoded signal are supplied, respectively, each of the unit input circuits includes an input wiring pattern that extends in the second direction, and a transistor of which a control electrode is electrically connected to the input wiring pattern included in a same unit input circuit, and coordinates of the input wiring pattern and the transistor corresponding to the input wiring pattern in the first direction do not overlap with each other.

In another embodiment, there is provided a semiconductor device comprising a plurality of circuit blocks arranged in a matrix form in a first direction and a second direction that intersects with the first direction, wherein each of the circuit blocks includes a plurality of unit input circuits to which a corresponding bit included in a pre-decoded signal are supplied, respectively, and a processing circuit block that processes an internal signal output from the unit input circuits, and a same bit included in the pre-decoded signal is supplied to two circuit blocks that are adjacent to each other in the second direction among the circuit blocks via a common input wiring pattern that extends in the second direction included in said two circuit blocks.

In still another embodiment, there is provided a semiconductor device comprising: an internal connection pattern arranged in a first wiring area that extends in a first direction; a signal line pattern arranged in a second wiring area that extends in the first direction; a power supply wiring pattern arranged in a third wiring area that extends in the first direction; a first unit circuit including: a transistor having a source region, a drain region, and a gate electrode; a source wiring pattern that is connected to the source region; a drain wiring pattern that is connected to the drain region; and an input wiring pattern that is connected to the gate electrode; and a second unit circuit including: a transistor having a source region, a drain region, and a gate electrode; a source wiring pattern that is connected to the source region; a drain wiring pattern that is connected to the drain region; and an internal wiring pattern that is connected to the gate electrode, wherein the second wiring area is sandwiched between the first and third wiring areas in a second direction that intersects with the first direction, the source wiring patterns, the drain wiring patterns, the input wiring pattern, and the internal wiring pattern extend in the second direction, the internal connection pattern, the signal line pattern and the power supply wiring pattern, and the source wiring patterns, the drain wiring patterns, the input wiring pattern and the internal wiring pattern are formed in different wiring layers from each other, the source wiring patterns of the first and second unit circuits have an overlap with at least the third wiring area, the drain wiring patterns of the first and second unit circuits have an overlap with at least the first wiring area, the input wiring pattern of the first unit circuit has an overlap with at least the second and third wiring areas, the internal wiring pattern of the second unit circuit has an overlap with at least the first wiring area, without having an overlap with the third wiring area, the input wiring pattern of the first unit circuit is connected to the signal line pattern, the source wiring patterns of the first and second unit circuits are connected to the power source wiring pattern, and the drain wiring pattern of the first unit circuit is connected to the internal wiring pattern of the second unit circuit via the internal connection pattern.

According to the present invention, because a signal is input through an input wiring pattern that extends along a second direction, it is possible for adjacent circuit blocks in the second direction to share the input wiring pattern. Accordingly, it is possible to reduce the number of pre-decode wirings that are laid out on a plurality of circuit blocks.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a layout diagram showing an overall configuration of a semiconductor device according to an embodiment of the present invention;

FIG. 2 is an enlarged view of the circuit area 11;

FIG. 3 is a block diagram for explaining a connection relationship between the fuse area 40 and the fuse latch circuit 70;

FIG. 4 is a schematic block diagram showing a configuration of the fuse latch circuit 70;

FIG. 5 is a block diagram showing a configuration of the latch circuit block 100;

FIG. 6 is a layout diagram of the unit input circuit 11A;

FIG. 7 is a layout diagram of the unit internal circuit 121;

FIG. 8 is a layout diagram of the latch circuit block 100;

FIG. 9 is a layout diagram for explaining a mutual relationship between two latch circuit blocks 100a and 100b that are adjacent to each other in the Y direction;

FIG. 10 is a layout diagram for explaining a mutual relationship between two latch circuit blocks 100c and 100d that are adjacent to each other in the X direction;

FIG. 11 is a layout diagram showing a plurality of latch circuit blocks 100e to 100p arranged in a matrix form;

FIG. 12 is a schematic layout diagram focusing attention on a bit IN_A in the layout shown in FIG. 11;

FIG. 13 is a schematic layout diagram focusing attention on a bit IN_B in the layout shown in FIG. 11;

FIG. 14 is a schematic layout diagram focusing attention on a bit IN_C in the layout shown in FIG. 11; and

FIG. 15 is a schematic layout diagram for explaining a problem that occurs when the input wiring patterns 200 are not used.

### DETAILED DESCRIPTION OF THE EMBODIMENTS

Preferred embodiments of the present invention will be explained below in detail with reference to the accompanying drawings.

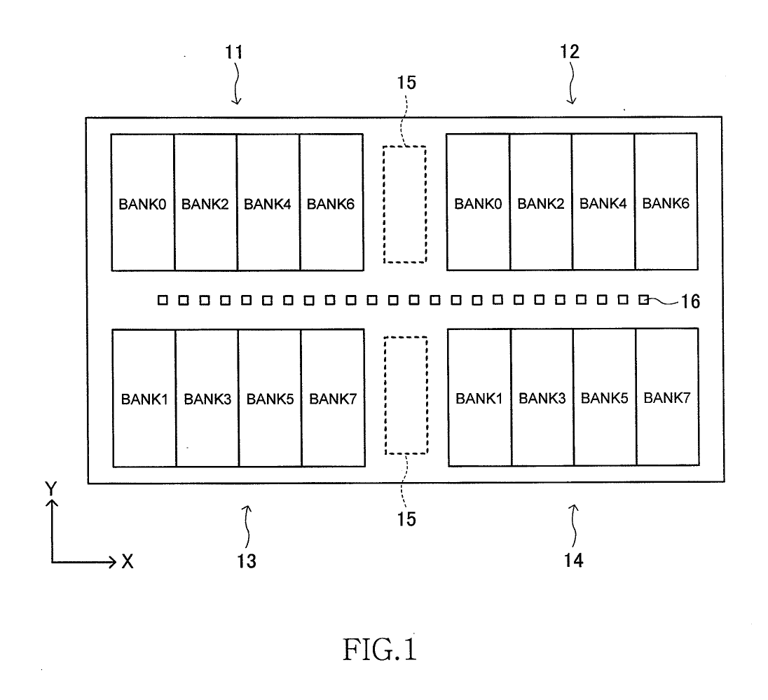

FIG. 1 is a layout diagram showing an overall configuration of a semiconductor device according to an embodiment of the present invention.

The semiconductor device according to the present embodiment is a semiconductor memory such as a DRAM, and, as shown in FIG. 1, the semiconductor device includes four circuit areas 11 to 14 that are arranged in a matrix form with two rows in an X direction and two columns in a Y direction. A half of even-numbered banks or odd-numbered banks is formed in one circuit area. Specifically, a half of even-numbered banks (BANK0, BANK2, BANK4, and BANK6) is formed in the circuit area 11, and the rest half of the banks (BANK0, BANK2, BANK4, and BANK6) is formed in the circuit area 12. A half of odd-numbered banks (BANK1, BANK3, BANK5, and BANK7) is formed in the circuit area 13, and the rest half of the banks (BANK1, BANK3, BANK5, and BANK7) is formed in the circuit area 14. Peripheral circuits 15, external terminals 16 and the like are arranged between the circuit areas.

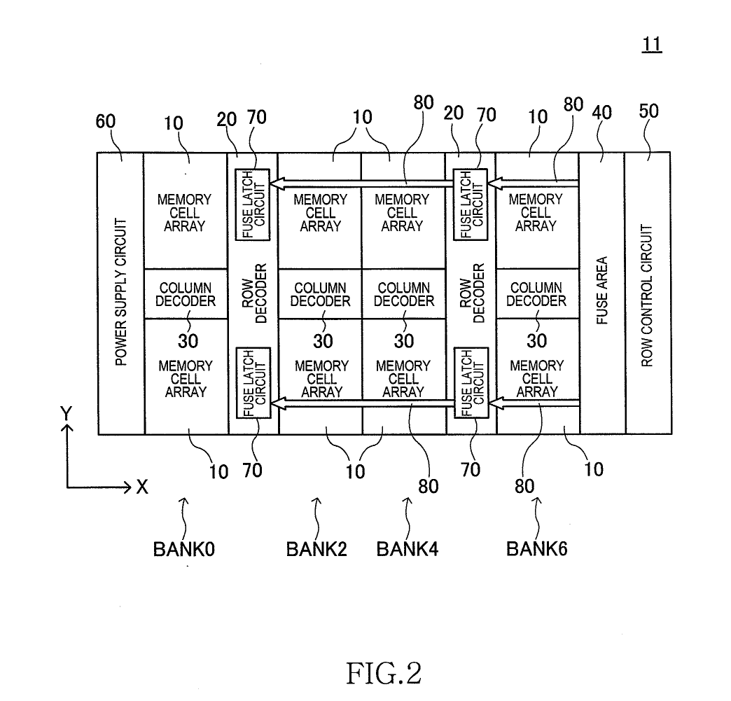

FIG. 2 is an enlarged view of the circuit area 11.

As shown in FIG. 2, the circuit area 11 includes row decoders 20, column decoders 30, a fuse area 40, a row control circuit 50, and a power supply circuit 60, as well as memory cell arrays 10 that constitute the banks BANK0, BANK2, BANK4, and BANK6. The row decoders 20 are arranged between the bank BANK0 and the bank BANK2 and between the bank BANK4 and the bank BANK6, respectively, and perform selection of a word line included in the memory cell arrays 10 based on a control by the row control circuit 50. Each of the memory cell arrays 10 is divided into two parts in the Y direction, and each of the column decoders 30 is arranged between two divided memory cell arrays in each of the banks. The column decoders 30 perform selection of a bit line included in the memory cell arrays 10. When a bit line to be selected is a defective bit line, the column decoders 30 perform an alternative access to a redundant bit line instead of the bit line that is indicated by a column address. A control for the alternative access is performed by a fuse latch circuit 70 that is provided in each of the row decoders 20.

A redundant signal supplied from the fuse area 40 is supplied to the fuse latch circuit 70. A plurality of fuse elements (not shown) are arranged in the fuse area 40, in which a column address corresponding to the defective bit line is stored. A wiring 80 that connects the fuse area 40 and the fuse latch circuit 70 is formed above the memory cell arrays 10 so as to cross them. Therefore, the wiring 80 becomes a relative long wiring. As is explained below, a redundant signal that is transmitted through the wiring 80 is an encoded signal by which the number of wirings 80 is reduced considerably.

As for the circuit areas 12 to 14, because these areas have a circuit configuration identical to that of the circuit area 11 shown in FIG. 2, redundant explanations thereof will be omitted.

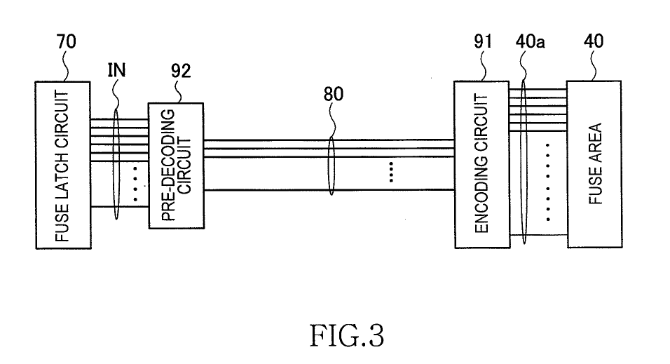

FIG. 3 is a block diagram for explaining a connection relationship between the fuse area 40 and the fuse latch circuit 70.

As shown in FIG. 3, a redundant signal output from the fuse area 40 is supplied to an encoding circuit 91 through wirings 40a. Because the output of the fuse area 40 is a signal that is not encoded, the number of bits of the signal is considerably large, and the number of the wirings 40a is considerably large accordingly. The encoding circuit 91 is a circuit that is arranged near the fuse area 40 and that reduces the number of bits of the redundant signal by encoding the redundant signal output from the fuse area 40 to a binary-coded form. The encoded redundant signal is transmitted through the wiring 80 that passes above the memory cell arrays 10 as described above.

The redundant signal transmitted through the wiring 80 is supplied to a pre-decoding circuit 92. The pre-decoding circuit 92 is arranged near the fuse latch circuit 70 and generates a pre-decoded redundant signal by partially decoding the encoded redundant signal. The pre-decoded redundant signal is supplied to the fuse latch circuit 70 through pre-decode wirings IN.

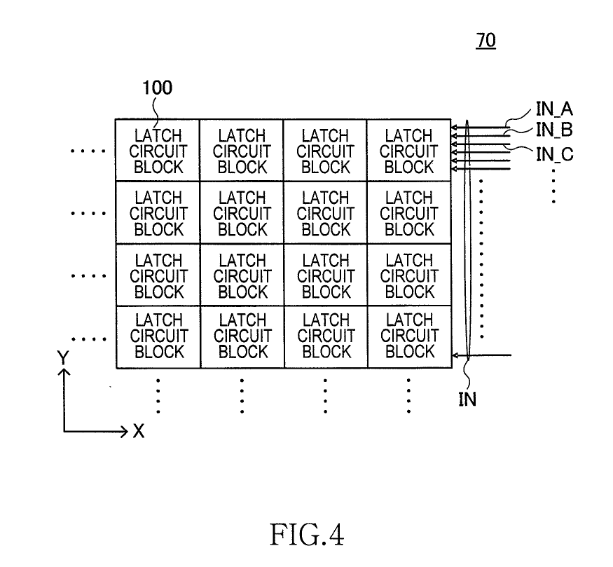

FIG. 4 is a schematic block diagram showing a configuration of the fuse latch circuit 70.

As shown in FIG. 4, the fuse latch circuit 70 is constituted by a plurality of latch circuit blocks 100 arranged in a matrix form in the X direction and the Y direction. The pre-decode wirings IN through which a pre-decoded signal is transmitted extend in the X direction. Among pre-decoded signals that are supplied through the pre-decode wirings IN, a part of bits is supplied to its corresponding one of the latch circuit blocks 100. At this time, each of bits IN A, IN_B, IN_C, . . . that constitute the pre-decoded signal is shared by some of the latch circuit blocks 100. While it is described later in detail, when the same bit of the pre-decoded signal is input to at least two of the latch circuit blocks 100, an input wiring pattern that extends in the Y direction is used, by which the pre-decode wirings IN that extend in the X direction are branched in the Y direction.

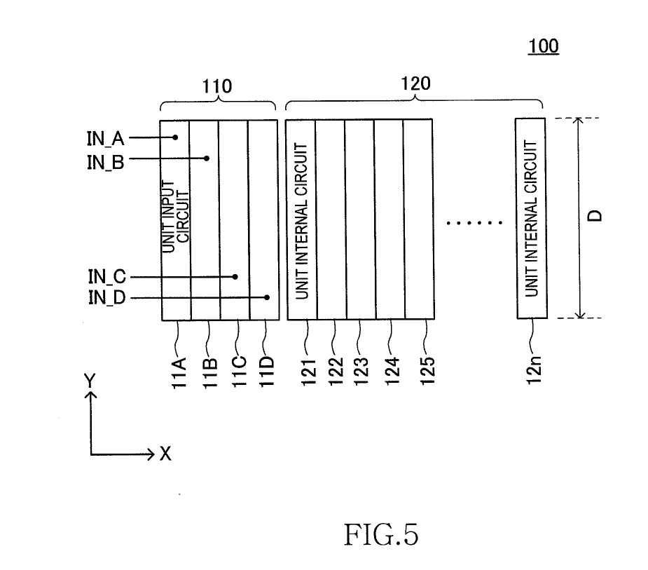

FIG. 5 is a block diagram showing a configuration of the latch circuit block 100.

As shown in FIG. 5, the latch circuit block 100 includes an input circuit block 110 and a processing circuit block 120. The input circuit block 110 and the processing circuit block 120 are arranged in the X direction with a same length D in the Y direction. The input circuit block 110 is a circuit part to which a plurality of bits included in a pre-decoded signal are input, and the processing circuit block 120 is a circuit part that receives and latches an internal signal output from the input circuit block 110.

The input circuit block 110 is constituted by a plurality of unit input circuits 11A, 11B, arranged in the X direction, to which corresponding ones of the bits IN_A, IN_B, . . . of the pre-decoded signal are input, respectively. As shown in FIG. 5, the unit input circuits 11A, 11B, . . . have the same shape with the Y direction as its longitudinal direction. Meanwhile, the processing circuit block 120 is constituted by a plurality of unit internal circuits 121, 122, . . . arranged in the X direction. As shown in FIG. 5, the unit internal circuits 121, 122, . . . also have the same shape with the Y direction as its longitudinal direction.

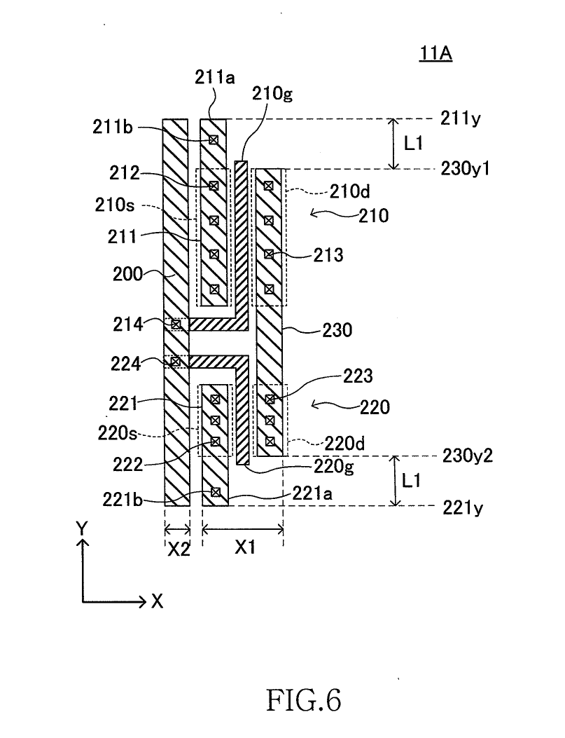

FIG. 6 is a layout diagram of the unit input circuit 11A.

As shown in FIG. 6, the unit input circuit 11A includes an input wiring pattern 200 that extends in the Y direction, a P-channel MOS transistor 210, and an N-channel MOS transistor 220. The transistors 210 and 220 are arranged next to each other along the Y direction with a same coordinate X1 in the X direction. The input wiring pattern 200 substantially coincides with a length of the unit input circuit 11A in the Y direction. Therefore, a coordinate X2 of the input wiring pattern 200 in the X direction does not overlap with the coordinate X1.

The transistor 210 includes a source area 210s and a drain area 210d arranged side by side in the X direction and a gate electrode 210g arranged in an upper part between the source area 210s and the drain area 210d. The source area 210s is connected to a source wiring pattern 211 via a contact conductor 212, and the drain area 210d is connected to a drain wiring pattern 230 via a contact conductor 213. The gate electrode 210g is connected to the input wiring pattern 200 via a contact conductor 214.

Similarly, the transistor 220 includes a source area 220s and a drain area 220d arranged side by side in the X direction and a gate electrode 220g arranged in an upper part between the source area 220s and the drain area 220d. The source area 220s is connected to a source wiring pattern 221 via a contact conductor 222, and the drain area 220d is connected to the drain wiring pattern 230 via a contact conductor 223. The gate electrode 220g is connected to the input wiring pattern 200 via a contact conductor 224.

The wiring patterns 200, 211, 221, and 230 are formed in the same wiring layer, and extend in the Y direction. Among the wiring patterns, the drain wiring pattern 230 is a common wiring to the transistors 210 and 220, and is used as an output node of the unit input circuit 11A. Y coordinates 230y1 and 230y2 of edges of the drain wiring pattern 230 substantially match the Y coordinates of edges of the drain areas 210d and 220d of the transistors 210 and 220.

On the other hand, an upper edge of the source wiring pattern 211 protrudes above an upper edge of the drain wiring pattern 230. That is, a Y coordinate 211y of the upper edge of the source wiring pattern 211 is away from the Y coordinate 230y1 of the upper edge of the drain wiring pattern 230 by a distance L1. A contact conductor 211b for connecting to a power source wiring (not shown) is formed on a protruding portion 211a of the source wiring pattern 211.

Similarly, a lower edge of the source wiring pattern 221 protrudes below a lower edge of the drain wiring pattern 230. That is, a Y coordinate 221y of the lower edge of the source wiring pattern 221 is away from the Y coordinate 230y2 of the lower edge of the drain wiring pattern 230 by a distance L1. A contact conductor 221b for connecting to a ground wiring (not shown) is formed on a protruding portion 221a of the source wiring pattern 221.

The Y coordinate of an upper edge of the input wiring pattern 200 substantially matches the Y coordinate 211y of the upper edge of the source wiring pattern 211, and the Y coordinate of a lower edge of the input wiring pattern 200 substantially matches the Y coordinate 221y of the lower edge of the source wiring pattern 221. In this manner, in the unit input circuit 11A, the input wiring pattern 200 and the source wiring patterns 211 and 221 are protruding up and down in the Y direction.

With this configuration, the unit input circuit 11A constitutes an inverter circuit. An input node of the inverter circuit is the input wiring pattern 200, and an output node is the drain wiring pattern 230. Other unit input circuits 11B, 11C, . . . have a configuration identical to that of the unit input circuit 11A shown in FIG. 6, and such unit input circuits are arranged in the X direction as shown in FIG. 5. An output node of each of the unit input circuits 11A, 11B, . . . is connected to an input node of a predetermined one of the unit internal circuits 121, 122, . . . included in the same latch circuit block 100.

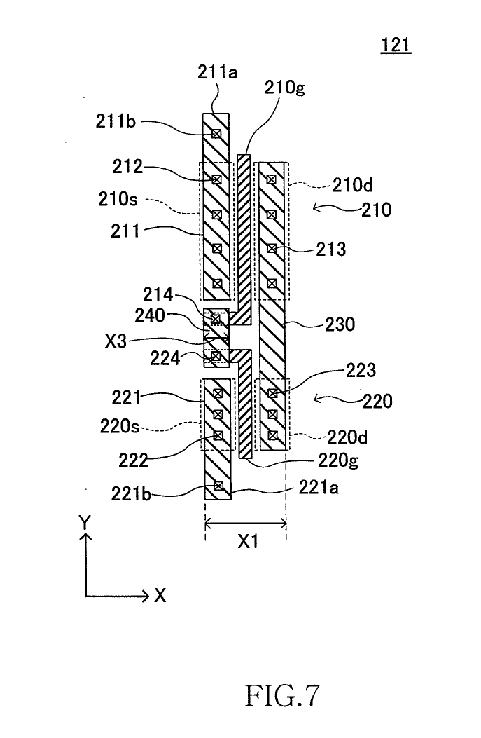

FIG. 7 is a layout diagram of the unit internal circuit 121.

As shown in FIG. 7, the unit internal circuit 121 has a configuration identical to that of the unit input circuit 11A shown in FIG. 6, except for a configuration that the input wiring pattern 200 is replaced with an internal wiring pattern 240. The internal wiring pattern 240 is formed in the same wiring layer as the wiring patterns 211, 221, and 230, which is arranged between the source wiring patterns 211 and 221 in a straight line in the Y direction. Therefore, a coordinate X3 of the internal wiring pattern 240 in the X direction overlaps with the coordinated X1 of the transistors 210 and 220 in the X direction.

With this configuration, the unit internal circuit 121 constitutes an inverter circuit. An input node of the inverter circuit is the internal wiring pattern 240, and an output node is the drain wiring pattern 230. Other unit internal circuits 122, 123, . . . have a configuration identical to that of the unit internal circuit 121 shown in FIG. 7, and such unit internal circuits are arranged in the X direction as shown in FIG. 5. An output node of each of the unit internal circuits 121, 122, 123, . . . is connected to an input node of a predetermined one of the unit internal circuits 121, 122, . . . included in the same latch circuit block 100, by which a latch circuit and the like are constituted.

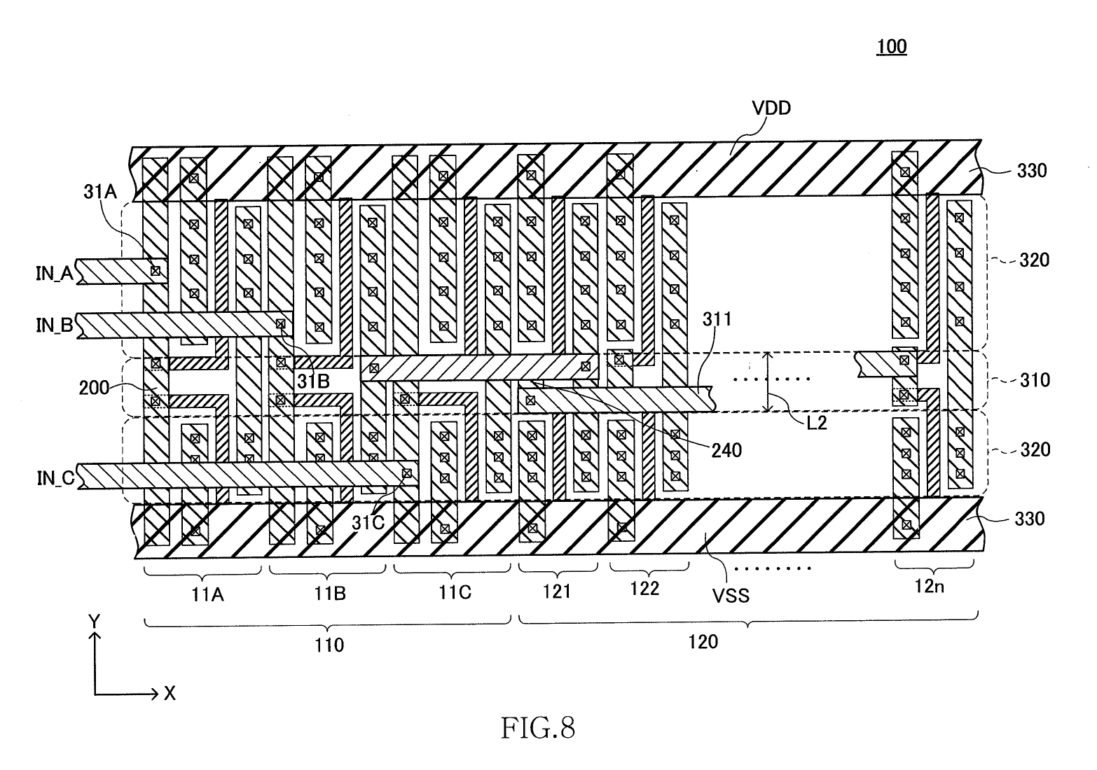

FIG. 8 is a layout diagram of the latch circuit block 100.

The latch circuit block 100 shown in FIG. 8 is a circuit block to which the bits IN_A, IN_B, and IN_C included in the pre-decoded signal are input, as an example, including the unit input circuits 11A, 11B, and 11C corresponding to the bits, respectively. The latch circuit block 100 further includes a plurality of unit internal circuits 121, 122, . . . . A length L2 of the internal wiring pattern 240 included in the unit internal circuits 121, 122, . . . is defined as an internal wiring area 310 that extends in the X direction. That is, the internal wiring patterns 240 of the unit internal circuits 121, 122, . . . have the same Y coordinate, so that the internal wiring area 310 forms a shape extending in the X direction. An internal connection pattern 311 for connecting parts in the latch circuit block 100 is formed in the internal wiring area 310 so as to extend in the X direction. The internal connection pattern 311 is formed in an upper wiring layer than the wiring patterns 200, 211, 221, and 230 described above.

Meanwhile, both sides sandwiching the internal wiring area 310 in the Y direction are used as layout wiring areas 320. The layout wiring areas 320 are areas in which a signal line pattern such as the pre-decode wiring IN is arranged, in which the same wiring layer as the internal wiring area 310 is employed. The unit input circuits 11A, 11B, and 11C and the pre-decode wirings IN_A, IN_B, and IN_C corresponding to the unit input circuits 11A, 11B, and 11C are connected to each other via contact conductors 31A, 31B, and 31C formed on the layout wiring areas 320, respectively.

In this manner, the internal wiring area 310 and the layout wiring areas 320 have different coordinates in the Y direction from each other, and thus, when wirings are formed in the wiring areas 310 and 320 in the X direction, they do not cause an interference with each other.

Both sides sandwiching the internal wiring area 310 and the layout wiring areas 320 in the Y direction are used as power supply mainline areas 330. The power supply mainline areas 330 are areas in which a power supply wiring pattern such as a power supply wiring VDD and a ground wiring VSS is arranged in the X direction, in which the same wiring layer as the internal wiring area 310 and the layout wiring areas 320 is employed. The power supply mainline areas 330 are provided at a position overlapping with the protruding portions 211a and 221a of the source wiring patterns 211 and 221 in a planar view. With this arrangement, the power supply wiring VDD and the source wiring pattern 211 are connected to each other via the contact conductor 211b, and similarly, the ground wiring VSS and the source wiring pattern 221 are connected to each other via the contact conductor 221b.

The layout configuration of the latch circuit block 100 is as explained above. A mutual relationship between a plurality of adjacent latch circuit blocks 100 is explained next.

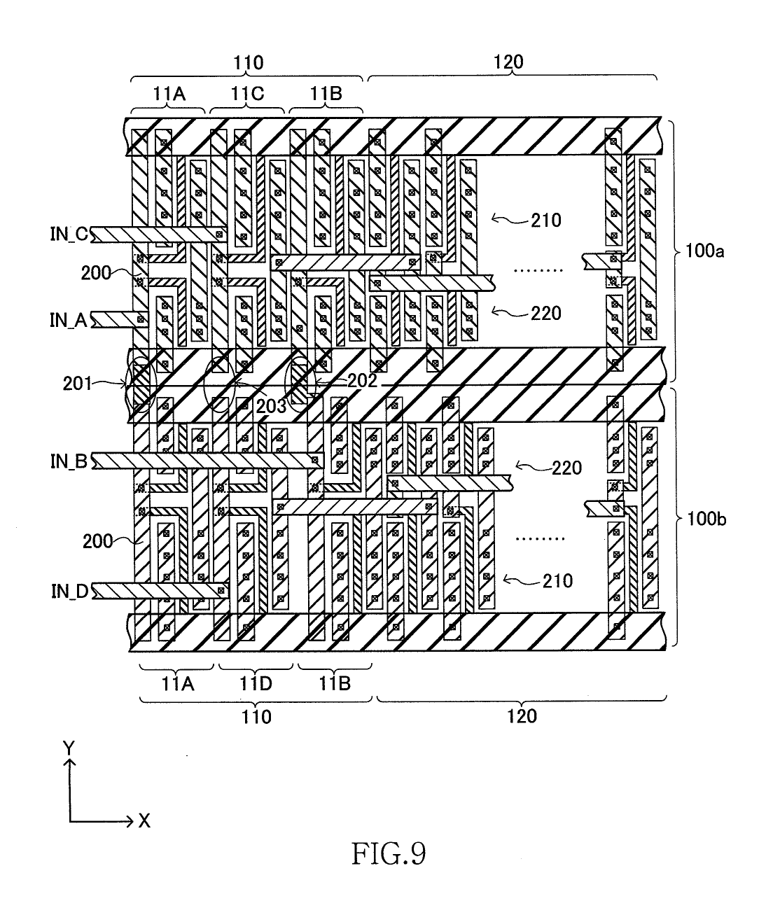

FIG. 9 is a layout diagram for explaining a mutual relationship between two latch circuit blocks 100a and 100b that are adjacent to each other in the Y direction.

In the example shown in FIG. 9, the bits IN_A, IN_B, and IN_C included in the pre-decoded signal are input to the latch circuit block 100a, and the bits IN_A, IN_B, and IN_D included in the pre-decoded signal are input to the latch circuit block 100b. In this manner, the latch circuit blocks 100a and 100b share the two bits IN_A and IN_B included in the pre-decoded signal with each other. Beside, because the pre-decode wiring IN is provided to be extending in the X direction, in a conventional layout, it is required to form the wirings through which the bits IN_A and IN_B are supplied for each of the latch circuit blocks 100a and 100b.

However, in the present embodiment, because the input wiring pattern 200 is provided to be extending in the Y direction, it is possible to share the same input bit in the two latch circuit blocks 100a and 100b that are adjacent to each other in the Y direction.

Specifically, as shown in FIG. 9, because the unit input circuit 11A in the latch circuit block 100a and the unit input circuit 11A in the latch circuit block 100b have the same coordinate in the X direction, it is possible to connect them by extending the input wiring patterns 200 included in the unit input circuits 11A in the Y direction. That is, by using a connection wiring 201, it is possible to connect the two input wiring patterns 200 to each other. Therefore, one wiring is enough to supply the bit IN_A to the two latch circuit blocks 100a and 100b.

As shown in FIG. 9, although the unit input circuit 11B in the latch circuit block 100a and the unit input circuit 11B in the latch circuit block 100b do not have the completely same coordinate in the X direction, a part of them overlaps with each other. By using a connection wiring 202 formed in a crank shape for slightly shifting the coordinate in the X direction, it is possible to connect the input wiring patterns 200 included in the unit input circuits 11B to each other. Therefore, one wiring is enough to supply the bit IN_B to the two latch circuit blocks 100a and 100b. Such a misalignment occurs in the X direction because the configurations of all the latch circuit blocks are not completely the same, which means that a circuit block having a slightly different configuration from the other latch circuit blocks is included, such as a latch circuit block that receives a test signal.

On the other hand, as shown in FIG. 9, because the bit signals input to the unit input circuit 11C in the latch circuit block 100a and the unit input circuit 11D in the latch circuit block 100b are different from each other although they have the same coordinate in the X direction, it suffices that the input wiring patterns 200 included in the unit input circuits 11C and 11D are split off with a split portion 203.

In this manner, in the present embodiment, because the input wiring pattern 200 that extends in the Y direction is provided in the unit input circuit and because the coordinate of the input wiring pattern 200 in the X direction and the coordinates of the corresponding transistors 210 and 220 in the X direction do not overlap with each other, the two latch circuit blocks 100a and 100b that are adjacent to each other in the Y direction can share the same input bit by using the connection wirings 201 and 202.

In the example shown in FIG. 9, in the latch circuit block 100a, the P-channel MOS transistors 210 are arranged in an upper part in the Y direction and the N-channel MOS transistors 220 are arranged in a lower part in the Y direction. On the other hand, in the latch circuit block 100b, the N-channel MOS transistors 220 are arranged in an upper part in the Y direction and the P-channel MOS transistors 210 are arranged in a lower part in the Y direction. In this manner, by arranging the transistors 210 and 220 in opposite positions in the two latch circuit blocks that are adjacent to each other in the Y direction, it is possible to use the same well in the two latch circuit blocks that are adjacent to each other in the Y direction. In the example shown in FIG. 9, it is possible to form the N-channel MOS transistors 220 arranged in the lower part of the latch circuit block 100a in the Y direction and the N-channel MOS transistors 220 arranged in the upper part of the latch circuit block 100b in the Y direction in the same well. With this arrangement, use efficiency of the semiconductor substrate can be enhanced, and thus high integration of the semiconductor chip can be achieved.

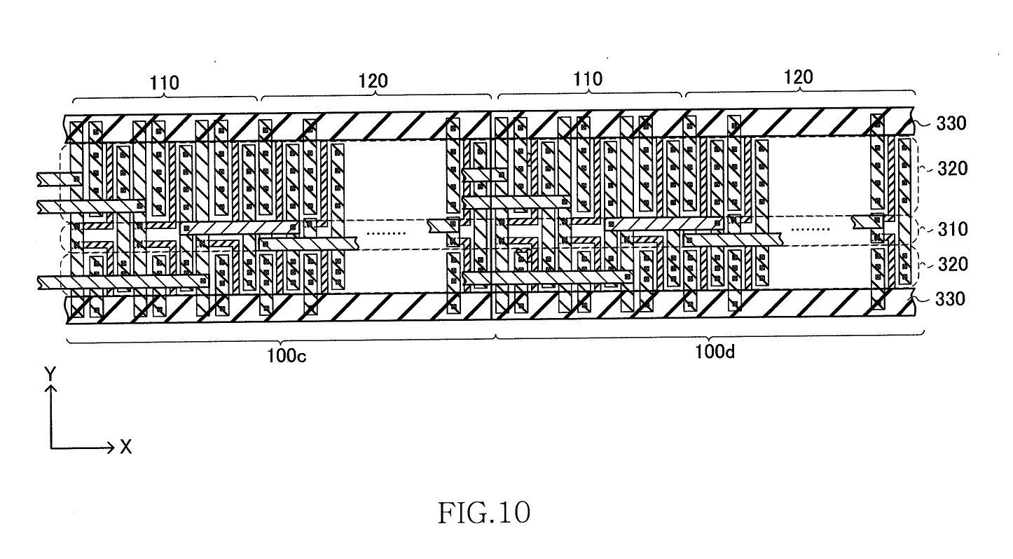

FIG. 10 is a layout diagram for explaining a mutual relationship between two latch circuit blocks 100c and 100d that are adjacent to each other in the X direction.

As shown in FIG. 10, in the present embodiment, the internal wiring areas 310 of the two latch circuit blocks 100c and 100d that are adjacent to each other in the X direction have the same Y coordinate. Therefore, because the Y coordinates of the layout wiring areas 320 also match each other, it is possible to extend the layout wiring areas 320 in a straight line in the X direction. With this arrangement, it is possible to secure a sufficient number of wirings that can be arranged in the layout wiring areas 320.

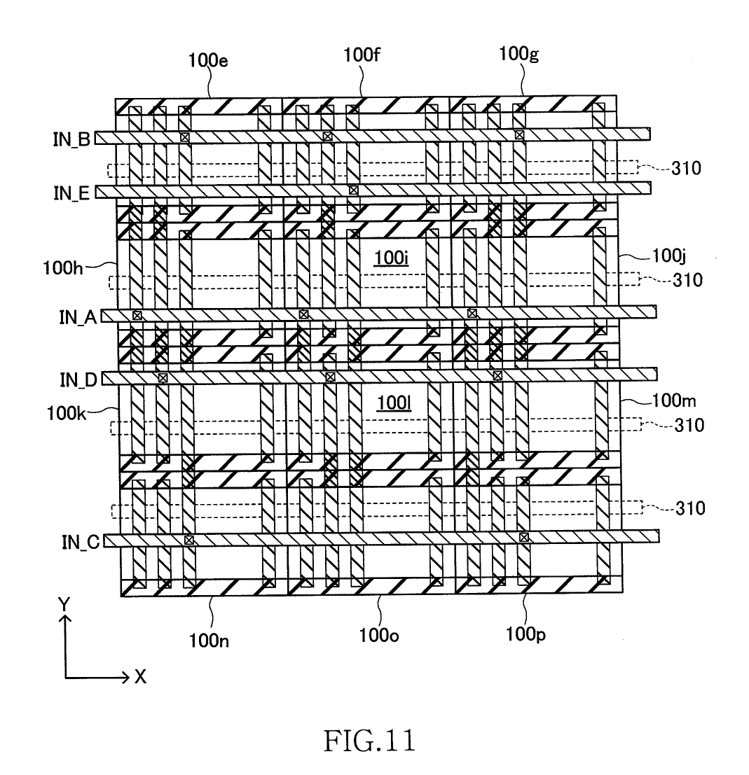

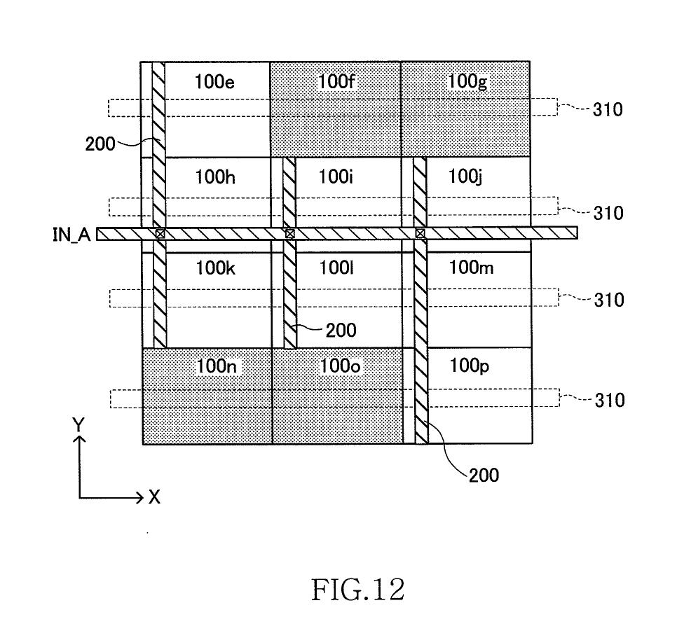

FIG. 11 is a layout diagram showing a plurality of latch circuit blocks 100e to 100p arranged in a matrix form, and FIGS. 12 to 14 are schematic layout diagrams showing the latch circuit blocks 100e to 100p focusing on the input bits IN_A to IN_C, respectively. In FIGS. 12 to 14, latch circuit blocks on which hatching is not applied are circuit blocks that requires the input bits IN_A to IN_C, and latch circuit blocks on which hatching is applied are circuit blocks that do not require the input bits IN_A to IN_C.

As shown in FIGS. 11 and 12, in the present embodiment, the eight latch circuit blocks 100e, 100h to 100m, and 100p are the circuit blocks that require the input bit IN_A, and the other latch circuit blocks 100 are the circuit blocks that do not require the input bit IN_A. In this case, one wiring through which the bit signal IN_A is supplied is extended in the X direction on the latch circuit blocks 100h to 100j, and among the eight latch circuit blocks 100e, 100h to 100m, and 100p that require the input bit IN_A, the input wiring patterns 200 to which the input bit IN_A is supplied are short-circuited between circuit blocks that are adjacent to each other in the Y direction. With this arrangement, even though the eight latch circuit blocks 100e, 100h to 100m, and 100p that require the input bit IN_A are spread in the Y direction, the number of wirings of the bit signal IN_A extending in the X direction can be reduced to one.

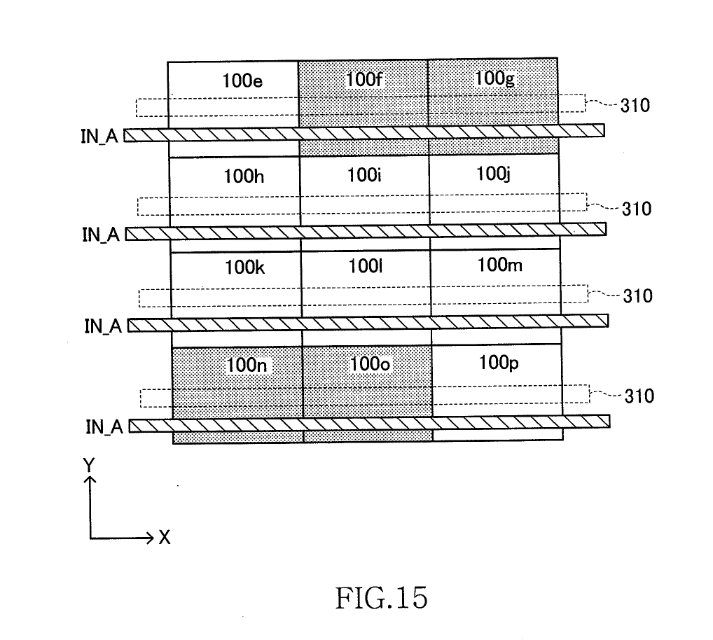

FIG. 15 is a schematic layout diagram for explaining a problem that occurs when the input wiring patterns 200 are not used in the latch circuit blocks 100e to 100p shown in FIG. 11. As shown in FIG. 15, when the input wiring patterns 200 are not used, because four wirings need to be formed in the X direction to supply the bit signal IN_A, it turns out that the wiring density in the layout wiring areas 320 is considerably increased.

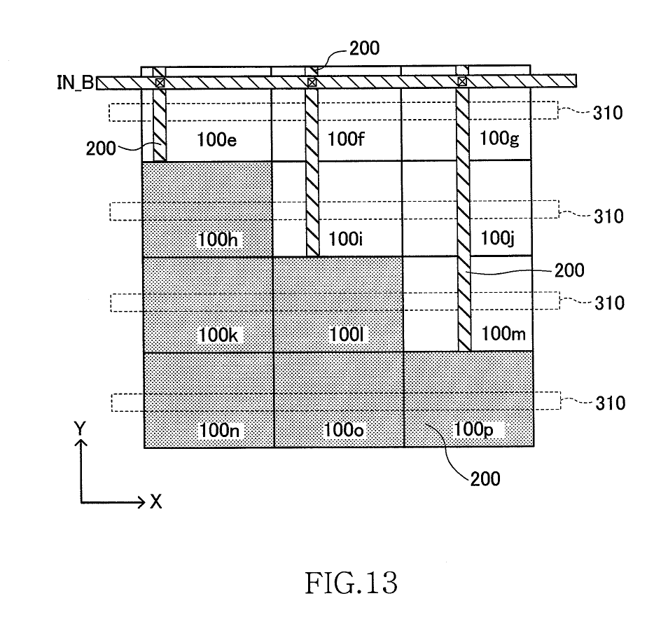

As shown in FIGS. 11 and 13, in the present embodiment, the seven latch circuit blocks 100e to 100g, 100i, 100j, and 100m are the circuit blocks that require the input bit IN_B, and the other latch circuit blocks 100 are the circuit blocks that do not require the input bit IN_B. In this case, one wiring through which the bit signal IN_B is supplied is extended in the X direction on the latch circuit blocks 100e to 100g, and among the seven latch circuit blocks 100e to 100g, 100i, 100j, and 100m that require the input bit IN_B, the input wiring patterns 200 to which the input bit IN_B is supplied are short-circuited between circuit blocks that are adjacent to each other in the Y direction. With this arrangement, even though the seven latch circuit blocks 100e to 100g, 100i, 100j, and 100m that require the input bit IN_B are spread in the Y direction, the number of wirings of the bit signal IN_B extending in the X direction can be reduced to one.

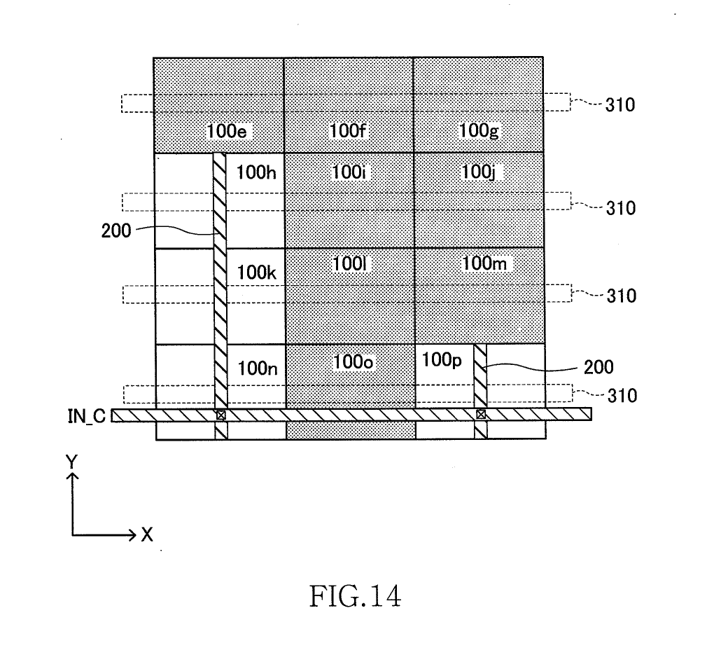

Furthermore, as shown in FIGS. 11 and 14, in the present embodiment, the four latch circuit blocks 100h, 100k, 100n, and 100p are the circuit blocks that require the input bit IN_C, and the other latch circuit blocks 100 are the circuit blocks that do not require the input bit IN_C. In this case, one wiring through which the bit signal IN_C is supplied is extended in the X direction on the latch circuit blocks 100n to 100p, and among the four latch circuit blocks 100h, 100k, 100n, and 100p that require the input bit IN_C, the input wiring patterns 200 to which the input bit IN_C is supplied are short-circuited between circuit blocks that are adjacent to each other in the Y direction. With this arrangement, even though the four latch circuit blocks 100h, 100k, 100n, and 100p that require the input bit IN_C are spread in the Y direction, the number of wirings of the bit signal IN_C extending in the X direction can be reduced to one.

It is apparent that the present invention is not limited to the above embodiments, but may be modified and changed without departing from the scope and spirit of the invention.

For example, although the pre-decoded redundant signal is input to each of the plural latch circuit blocks 100 in the above embodiment, in the present invention, it is not essential that the pre-decoded signal to be input to the circuit blocks should be a redundant signal. In addition, for example, without limiting to a plurality of pre-decoded signals of a fuse unit, even for an ASIC (Application Specific Integrated Circuit) or a gate array, it is also possible to build a layout wiring as explained above in a configuration in which, with respect to a plurality of circuit blocks arranged in a matrix form, one of a plurality of signals (corresponding to one of the pre-decoded signals described above) is input to a part of the circuit blocks and another one of the signals (corresponding to another one of the pre-decoded signals described above) is input to another part of the circuit blocks.

Further, in the examples shown in FIGS. 11 to 14, although only one wiring is used in the X direction to which the input bits IN_A, IN_B, and IN_C are supplied, respectively, in the present invention, it is not essential that each of the wirings should be reduced to one. Therefore, in the examples shown in FIGS. 11 and 12, for example, it is acceptable to form two wirings to supply the input bit IN_A in the X direction. In this case, although the wiring density in the layout wiring areas 320 becomes higher than that in the above embodiment, flexibility of design in the wiring layer in which the input wiring pattern 200 is formed is enhanced. Therefore, reduction of the number of wirings in the X direction can be determined considering the wiring density of an upper layer and flexibility of design in a lower layer.

What is claimed is:

1. A semiconductor device comprising a plurality of circuit blocks arranged in a matrix form in a first direction and a second direction that intersects with the first direction, wherein
each of the circuit blocks includes an input circuit block to which a plurality of bits included in a pre-decoded signal are supplied, and a processing circuit block that processes an internal signal output from the input circuit block,
the input circuit block and the processing circuit block are arranged side by side in the first direction,
the input circuit block includes a plurality of unit input circuits that is arranged in the first direction and to which corresponding bits of the pre-decoded signal are supplied, respectively,
each of the unit input circuits includes an input wiring pattern that extends in the second direction, and a transistor of which a control electrode is electrically connected to the input wiring pattern included in a same unit input circuit, and
coordinates of the input wiring pattern and the transistor corresponding to the input wiring pattern in the first direction do not overlap with each other.

2. The semiconductor device as claimed in claim 1, wherein
the processing circuit block includes a plurality of unit internal circuits arranged in the first direction,
each of the unit internal circuits includes an internal wiring pattern that extends in the second direction, and a transistor of which a control electrode is electrically connected to the internal wiring pattern included in a same unit internal circuit, and
at least parts of coordinates of the internal wiring pattern and the transistor corresponding to the internal wiring pattern in the first direction overlap with each other.

3. The semiconductor device as claimed in claim 1, wherein the transistor includes a P-channel MOS transistor and an N-channel transistor arranged side by side in the second direction.

4. The semiconductor device as claimed in claim 1, wherein the processing circuit block latches the internal signal that is generated based on the pre-decoded signal.

5. The semiconductor device as claimed in claim 4, wherein
the pre-decoded signal is a signal that is supplied from a fuse area that stores therein an address of a defective word line or a defective bit line included in a memory cell array, and
the memory cell array is arranged between the fuse area and the circuit blocks.

6. The semiconductor device as claimed in claim 1, wherein input wiring patterns included in two circuit blocks among the circuit blocks are electrically connected to each other, said two circuit blocks are arranged adjacent to each other in the second direction, and said two circuit blocks are supplied with a same bit among a plurality of bits constituting the pre-decoded signal.

7. The semiconductor device as claimed in claim 6, wherein coordinates in the first direction of said two unit input circuits overlap with each other.

8. The semiconductor device as claimed in claim 2, wherein
each of the circuit blocks includes an internal wiring area in which the internal wiring pattern is arranged, and a layout wiring area arranged being adjacent to the internal wiring area in the second direction, in which at least a pre-decode wiring for transmitting the pre-decoded signal is arranged, and
the input wiring pattern is connected to the pre-decode wiring via a contact conductor formed in the layout wiring area.

9. The semiconductor device as claimed in claim 8, wherein coordinates in the second direction of internal wiring areas included in two circuit blocks that are adjacent to each other in the first direction among the circuit blocks substantially match each other.

10. A semiconductor device comprising:
a fuse circuit storing fuse information, and outputting a plurality of fuse signals related to the fuse information;
a plurality of fuse signal lines elongated in parallel to each other in a first direction, and each of the fuse signal lines receiving a corresponding one of the fuse signals; and
a plurality of circuit blocks arranged in the first direction, each of the circuit blocks including a plurality of unit input circuits arranged in line in a second direction substantially perpendicular to the first direction, each of the unit input circuits being electrically connected to an associated one of selected ones of the fuse signal lines, and the selected ones of the fuse signal lines in respective ones of the circuit blocks being different in combination from each other.

11. The semiconductor device as claimed in claim 10, wherein each of the unit input circuits of each of the circuit blocks has a transistor and the fuse signal lines are not overlapped with the transistor of each of the unit input buffers of each of the circuit blocks.

12. The semiconductor device as claimed in claim 10, further comprising a plurality of global fuse signal lines elongated in parallel to each other in the second direction, each of the global fuse signal lines electrically connected to the fuse signal lines, respectively, and each of the global fuse signal lines overlapping with one of the circuit blocks and not overlapping with the others of the circuit blocks.

13. The semiconductor device as claimed in claim 10, wherein the fuse circuit includes:
a fuse portion storing the fuse information, and the fuse portion outputting in parallel a plurality of fuse data related to the fuse information;
an encoding circuit portion receiving the fuse data in parallel, and encoding the fuse data to output encoded data; and
a decoding circuit decoding the encoded data to output the plurality of fuse signals.

14. A semiconductor device comprising:
an internal connection pattern arranged in a first wiring area that extends in a first direction;
a signal line pattern arranged in a second wiring area that extends in the first direction;
a power supply wiring pattern arranged in a third wiring area that extends in the first direction;
a first unit circuit including: a transistor having a source region, a drain region, and a gate electrode; a source wiring pattern that is connected to the source region; a drain wiring pattern that is connected to the drain region; and an input wiring pattern that is connected to the gate electrode; and
a second unit circuit including: a transistor having a source region, a drain region, and a gate electrode; a source wiring pattern that is connected to the source region; a drain wiring pattern that is connected to the drain region; and an internal wiring pattern that is connected to the gate electrode, wherein
the second wiring area is sandwiched between the first and third wiring areas in a second direction that intersects with the first direction,
the source wiring patterns, the drain wiring patterns, the input wiring pattern, and the internal wiring pattern extend in the second direction,
the internal connection pattern, the signal line pattern and the power supply wiring pattern, and the source wiring patterns, the drain wiring patterns, the input wiring pattern and the internal wiring pattern are formed in different wiring layers from each other,
the source wiring patterns of the first and second unit circuits have an overlap with at least the third wiring area,
the drain wiring patterns of the first and second unit circuits have an overlap with at least the first wiring area,
the input wiring pattern of the first unit circuit has an overlap with at least the second and third wiring areas,
the internal wiring pattern of the second unit circuit has an overlap with at least the first wiring area, without having an overlap with the third wiring area,
the input wiring pattern of the first unit circuit is connected to the signal line pattern,
the source wiring patterns of the first and second unit circuits are connected to the power source wiring pattern, and
the drain wiring pattern of the first unit circuit is connected to the internal wiring pattern of the second unit circuit via the internal connection pattern.
